(19) United States
(12) Patent Application Publication
(10) Pub. No.: US 2023/0395135 A1
(43) Pub. Date: Dec. 7, 2023

(54) TIMING FOR OPERATIONS IN MEMORY DEVICE STORING BITS IN MEMORY CELL PAIRS

(71) Applicant: Micron Technology, Inc., Boise, ID (US)

(72) Inventors: Ferdinando Bedeschi, Biassono (MB) (IT); Efrem Bolandrina, Fiorano al Serio (BG) (IT); Innocenzo Tortorelli, Cernusco sul Naviglio (MI) (IT)

(21) Appl. No.: 17/864,046

(22) Filed: Jul. 13, 2022

Related U.S. Application Data
(60) Provisional application No. 63/347,927, filed on Jun. 1, 2022.

(51) Int. Cl. G11C 11/4096; G11C 11/4091; G11C 11/4093; G11C 11/4076

(52) U.S. Cl. CPC G11C 11/4096; G11C 11/4091; G11C 11/4093; G11C 11/4076

(57) ABSTRACT

Systems, methods, and apparatus related to memory devices (e.g., storage class memory). In one approach, a memory device has a memory array including memory cells arranged as differential memory cell pairs, with each pair storing a single logical bit. The memory device has a controller that receives a command from a host to initiate a read operation. The memory cell pair is selected using bitlines and a common wordline. A partition of the memory array is accessed to read the data stored by the memory cell pair, and then store the read data in a latch for sending to the host. In response to accessing the partition, a counter is incremented. The controller statistically determines whether to perform a refresh operation for the partition based on comparing the current value of the counter to a value previously generated by a random number generator.

### RELATED APPLICATIONS

The present application claims priority to Prov. U.S. Pat. App. Ser. No. 63/347,927 filed Jun. 1, 2022, the entire disclosures of which application are hereby incorporated herein by reference.

### FIELD OF THE TECHNOLOGY

At least some embodiments disclosed herein relate to memory systems in general, and more particularly, but not limited to timing for operations in a memory device that stores single bits using memory cell pairs.

### BACKGROUND

Memory devices are widely used to store information in various electronic devices such as computers, wireless communication devices, cameras, digital displays, and the like. Information is stored by programming different states of a memory device. For example, binary devices have two states, often denoted by a logic “1” or a logic “0.” In other systems, more than two states may be stored. To access the stored information, a component of the electronic device may read, or sense, the stored state in the memory device. To store information, a component of the electronic device may write, or program, the state in the memory device.

Various types of memory devices exist, including magnetic hard disks, random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory cells may maintain their stored logic state for extended periods of time even in the absence of an external power source. Volatile memory cells may lose their stored state over time unless they are periodically refreshed by an external power source.

A storage device is an example of a memory device. Typical computer storage devices have controllers that receive data access requests from host computers and perform programmed computing tasks to implement the requests in ways that may be specific to the media and structure configured in the storage devices. In one example, a memory controller manages data stored in memory and communicates with a computer device. In some examples, memory controllers are used in solid state drives for use in mobile devices or laptops, or media used in digital cameras.

Firmware can be used to operate a memory controller for a particular storage device. In one example, when a computer system or device reads data from or writes data to a memory device, it communicates with the memory controller.

Memory devices typically store data in memory cells. In some cases, memory cells exhibit non-uniform, variable electrical characteristics that may originate from various factors including statistical process variations, cycling events (e.g., read or write operations on the memory cells), or a drift (e.g., a change in resistance of a chalcogenide alloy), among others.

In one example, reading a set of data (e.g., a codeword, or a page) is carried out by determining a read voltage (e.g., an estimated median of threshold voltages) of memory cells that store the set of data. In some cases, a memory device may include an array of PCM cells arranged in a 3D architecture, such as a cross-point architecture to store the set of data. PCM cells in a cross-point architecture may represent a first logic state (e.g., a logic 1, a SET state) associated with a first set of threshold voltages, or a second logic state (e.g., a logic 0, a RESET state) associated with a second set of threshold voltages. In some cases, data may be stored using encoding (e.g., error correction coding (ECC)) to recover data from errors in the data stored in the memory cells.

For resistance variable memory cells (e.g., PCM cells), one of a number of states (e.g., resistance states) can be set. For example, a single level cell (SLC) may be programmed to one of two states (e.g., logic 1 or 0), which can depend on whether the cell is programmed to a resistance above or below a particular level. As an additional example, various resistance variable memory cells can be programmed to one of multiple different states corresponding to multiple data states, e.g., 10, 01, 00, 11, 111, 101, 100, 1010, 1111, 0101, 0001, etc. Such cells may be referred to as multi state cells, multi-digit cells, and/or multi-level cells (MLCs).

The state of a resistance variable memory cell can be determined (e.g., read) by sensing current through the cell responsive to an applied interrogation voltage. The sensed current, which varies based on the resistance of the cell, can indicate the state of the cell (e.g., the binary data stored by the cell). The resistance of a programmed resistance variable memory cell can drift (e.g., shift) over time. Resistance drift can result in erroneous sensing of a resistance variable memory cell (e.g., a determination that the cell is in a state other than that to which it was programmed, among other issues).

A PCM cell, for example, may be programmed to a reset state (amorphous state) or a set state (crystalline state). A reset pulse (e.g., a pulse used to program a cell to a reset state) can include a relatively high current pulse applied to the cell for a relatively short period of time such that the phase change material of the cell melts and rapidly cools, resulting in a relatively small amount of crystallization. Conversely, a set pulse (e.g., a pulse used to program a cell to a set state) can include a relatively lower current pulse applied to the cell for a relatively longer time interval and with a slower quenching speed, which results in an increased crystallization of the phase change material.

A programming signal can be applied to a selected memory cell to program the cell to a target state. A read signal can be applied to a selected memory cell to read the cell (e.g., to determine the state of the cell). The programming signal and the read signal can be current and/or voltage pulses, for example.

### BRIEF DESCRIPTION OF THE DRAWINGS

The embodiments are illustrated by way of example and not limitation in the figures of the accompanying drawings in which like references indicate similar elements.

FIG. 1 shows a memory device that stores single bits in a memory array using memory cell pairs, in accordance with some embodiments.

FIG. 2 shows detectors used to determine a logic state of a memory cell pair and a feedback circuit to control digit line voltages, in accordance with some embodiments.

FIG. 3 shows exemplary digit line and wordline voltages applied to a memory cell pair during a read operation, in accordance with some embodiments.

FIG. 4 shows an example of a memory cell that includes a select device, in accordance with some embodiments.

FIG. 5 shows a memory device configured with a partition refresh manager according to one embodiment.

FIG. 6 shows bitline drivers and a wordline driver configured to apply voltages to a memory cell pair.

FIG. 7 shows an exemplary three-dimensional memory array structure, in accordance with some embodiments.

FIG. 8 shows an exemplary normal quantile (NQ) plot representing the statistical distributions of threshold voltages of memory cells, in accordance with some embodiments.

FIG. 9 shows exemplary timings associated with read and write operations for a memory cell pair in which the write operation is for a same state, in accordance with some embodiments.

FIG. 10 shows exemplary timings associated with read and write operations for a memory cell pair in which the write operation is for an opposite state, in accordance with some embodiments.

FIG. 11 shows exemplary timings associated with read and write operations for a memory cell pair in which the write operation uses additional drift cancellation and is for a same state, in accordance with some embodiments.

FIG. 12 shows exemplary timings associated with read and write operations for a memory cell pair in which the write operation uses additional drift cancellation and is for an opposite state, in accordance with some embodiments.

FIG. 13 shows a method for managing refresh operations for partitions of a memory array, in accordance with some embodiments.

FIG. 14 shows a method for reading data stored in a memory cell pair and determining whether to perform a refresh operation, in accordance with some embodiments.

### DETAILED DESCRIPTION

The following disclosure describes various embodiments for timings associated with various operations (e.g., read or write) in a memory device that stores single bits using memory cell pairs. In some cases, a controller of the memory device determines whether to periodically perform one or more memory refresh operations.

In some embodiments, read and write timings for the memory device correspond to read and write timings used for dynamic random access memory (DRAM). In one example, the memory device mimics an access protocol used for DRAM (e.g., the memory device is used as a functional equivalent or substitute for DRAM in a computer system). A disadvantage of DRAM is that each read is destructive, which requires that all memory cells read be refreshed. This is required for every read operation. In addition, all memory cells of the DRAM must be regularly refreshed, whether read or not read. This leads to increased energy consumption for performing the frequent refreshing of memory cells. Also, each read operation requires significant time to perform the refreshing. This decreases the bandwidth for accessing data stored in the DRAM.

In contrast to DRAM, because the memory device according to various embodiments described herein stores data in a non-volatile manner, refresh timings typically associated with the refreshing of DRAM devices can instead be used by the memory device to perform other operations, such as periodically refreshing selected memory cells in a memory array (e.g., a refresh every 500 to 2,000 reads of the memory cells) (e.g., refresh for drift cancellation).

At least some embodiments herein relate to memory devices that use bipolar operations for a memory array. For example, memory cells of the memory device are programmed by flipping or changing a polarity of programming voltages applied to the cells.

In some existing bipolar memory devices, bipolar select voltages are used to select memory cells of a memory array. In one example, the memory cells are arranged in a cross-point architecture (e.g., two-dimensional or three-dimensional). In one example, each memory cell is formed using a single select device. In one example, the select device includes a chalcogenide material that snaps or thresholds when a sufficient voltage is applied across the memory cell. In other embodiments, other phase change memory cells can be used in which the memory cell thresholds when a sufficient voltage is applied across the cell.

The memory device may, for example, store data used by a host device (e.g., a computing device of an autonomous vehicle, or another computing device that accesses data stored in the memory device). In one example, the memory device is a solid-state drive mounted in an electric vehicle.

In some cases, a memory device may include an array of memory cells arranged in a three-dimensional (3D) architecture, such as a cross-point architecture, to store the set of data. The memory cells in a cross-point architecture may, for example, represent a first logic state (e.g., a logic 1, a SET state) associated with a first set of threshold voltages, or a second logic state (e.g., a logic 0, a RESET state) associated with a second set of threshold voltages.

In other embodiments, the memory cells may be arranged in a three-dimensional (3D) vertical architecture. A 3D vertical architecture may include memory cells located at the crossing between a vertical access line (e.g., a bitline pillar), and each one of a plurality of second access lines (e.g., wordlines), formed in horizontal planes or decks parallel to each other.

More generally, an integrated circuit memory cell, such as a memory cell in a cross-point memory or a 3D vertical array, can be programmed to store data by the way of its state at a voltage applied across the memory cell. For example, if a memory cell is configured or programmed in such a state that allows a substantial current to pass the memory cell at a voltage in a predefined voltage region, the memory cell is considered to have been configured or programmed to store a first bit value (e.g., one or zero); and otherwise, the memory cell is storing a second bit value (e.g., zero or one).

Optionally, a memory cell can be configured or programmed to store more than one bit of data by being configured or programmed, for example, to have a threshold voltage in one of more than two separate voltage regions.

The threshold voltage of a memory cell is such that when the voltage applied across the memory cell is increased to above the threshold voltage, the memory cell changes rapidly or abruptly, snaps (e.g., for a chalcogenide memory cell), or changes (e.g., jumps) from a non-conductive state to a conductive state. The non-conductive state allows a small leak current to go through the memory cell; and in contrast, the conductive state allows more than a threshold amount of current to go through. Thus, a memory device can use a sensor (e.g., sense amplifier) to detect the change, or determine the conductive/non-conductive state of the memory device at one or more applied voltages, to evaluate or classify the level of the threshold voltage of the memory cell and thus its stored data.

The threshold voltage of a memory cell can be configured/programmed to be in different voltage regions used to represent different data values stored in the memory cell. For example, the threshold voltage of the memory cell can be programmed to be in any of four predefined voltage regions; and each of the regions can be used to represent the bit values of a different two-bit data item. Thus, when given a two-bit data item, one of the four voltage regions can be selected based on a mapping between two-bit data items and voltage regions; and the threshold voltage of the memory cell can be adjusted, programmed, or configured to be in the selected voltage region to represent or store the given two-bit data item. To retrieve, determine, or read the data item from the memory cell, one or more read voltages can be applied across the memory cell to determine which of the four voltage regions contain the threshold voltage of the memory cell. The identification of the voltage region that contains the threshold voltage of the memory cell provides the two-bit data item that has been stored, programmed, or written into the memory cell.

For example, a memory cell can be configured or programmed to store a one-bit data item in a Single Level Cell (SLC) mode, or a two-bit data item in a Multi-Level Cell (MLC) mode, or a three-bit data item in a Triple Level Cell (TLC) mode, or a four-bit data item in Quad-Level Cell (QLC) mode.

A memory device can be made up of memory cells that may be individually selected for purposes of performing operations such as, for example, reading and writing. A memory cell may store a piece of data such as, for example, a binary digit. Memory cells may be arranged in grid-like manner where they are selected by activating the row and the column of the memory cell. To select a memory cell, a conductive line corresponding to the row and a conductive line corresponding to the column may need to receive specific demarcation read voltages (VDMs). For example, data is encoded in a memory cell by modifying the cell properties to achieve a particular threshold voltage (Vt) of the cell. A cell is considered to turn on if the VDM is greater than the Vt of the cell. When VDM>Vt, the cell may conduct current. When VDM<Vt, the cell does not conduct current.

However, there can be disadvantages to using VDMs to read memory cells. For example, the circuitry used to generate VDMs may include complicated analog circuits such as current mirrors, reference voltage generators, and other biasing circuits that generate specific VDMs. Moreover, as a memory device is used over time, or as ambient temperature changes, different VDM levels may need to be generated. For example, a memory cell may experience Vt drift over time. As a result, a particular VDM level that may accurately measure the cell at the beginning of the cell's life (e.g., time zero), may not accurately measure the cell months or years later.

To address the disadvantages of VDMs above, some memory devices have an architecture that alleviates the need for managing and controlling demarcation read voltages (VDMs) when performing read operations. This is done by logically combining physical memory cells into a logical single bit. For example, this approach reduces the need for precise VDMs.

More specifically, a logical single bit is mapped to two physical cells, referred to as a memory cell pair (e.g., cell 1 and cell 2). Cell 1 and cell 2 of a memory cell pair store reciprocal values. For example, a logical binary “1” is stored such that cell 1 stores a binary “1” and cell 2 stores a binary “0.” And a logical binary “0” is stored such that cell 1 stores a binary “0” and cell 2 stores a binary “1.”

To address the above and other technical problems (e.g., energy consumption and reduced bandwidth of DRAM devices), various embodiments described herein provide a memory device that uses memory cell pairs to store single bits of data. The memory cell pairs do not require refreshing on every read access, such as required for DRAM. Instead, the memory cells can be refreshed periodically as determined by a controller or other logic of the memory device.

This periodic refreshing is not required on every access to memory cell pairs that store data being read by a host (e.g., access to a partition in a memory array that includes the memory cell pairs). Instead, for example, the controller can use a statistical selection algorithm to determine when to perform a refresh operation for the partition. In one example, this algorithm typically causes 20 to 40 (e.g., a probability distribution having an average of 30) refresh operations for every 16,000 read accesses to the partition.

In one embodiment, a memory device has a memory array including memory cells arranged as memory cell pairs. Each pair is configured to store a logical bit. The memory device has bias circuitry (e.g., drivers) configured to select a first memory cell pair having first and second memory cells by applying voltages to a wordline and to first and second bitlines to select the first and second memory cells. The bias circuitry is further configured to reduce a magnitude of one or more of the voltages on the first or second bitlines after a first one of the first or second memory cells switches (e.g., thresholds or snaps). In one example, the memory cell pair is one of 256 pairs on a row of the memory array, and all 256 cell pairs are selected using the same wordline.

The memory device also has sensing circuitry (e.g., sense amplifiers) configured to read data stored by the first memory cell pair (e.g., including all other memory cell pairs on the same row). The memory device has a buffer configured to store the first data read by the sensing circuitry. In one example, the buffer includes a latch for each of the sense amplifiers and is used to latch logic states (e.g., 0 or 1) determined for each memory cell pair.

It should be noted that digit lines are sometimes referred to herein as bitlines. Digit lines and bitlines are generally used herein as interchangeable terms. For example, a pillar may be referred to as being part of either a bitline or digit line.

In one embodiment, a memory array configures memory cell pairs using a differential cell structure. Each memory bit of the memory array is given by the two memory cells of the pair. One of the cells (e.g., cell A) exhibits a low (or high) threshold state, and the other cell (e.g., cell B) exhibits a high (or low) threshold state. Cells A and B have been programmed in a complementary way.

In one example, a single bit is given by the cell pair. For instance, the data stored by the bit is as follows:

Logic 0=cell A in high threshold (VTH) and cell B in low threshold (VTH)

Logic 1=cell A in low threshold (VTH) and cell B in high threshold (VTH)

In one embodiment, the memory device implements a memory access protocol that is similar to an access protocol as used by a DRAM. For example, this access protocol involves three phases or commands corresponding to (i) activate, (ii) read or write, and (iii) pre-charge commands (e.g., received by a controller from a host device).

In response to the controller receiving an activate command, a sense bias voltage ramp is applied to the couple of cells A, B to read the memory bit and store its content into a read latch (e.g., a sense amplifier latch). A subsequent read command is used to retrieve the data from the sense amplifier latch. A subsequent write command is used to change the data stored in the memory array by loading new data that is to be written into a different latch (e.g., a write buffer latch). A comparison of data stored in the read buffer to data stored in the write buffer determines if the logic state of the memory bit needs to be changed in light of the logic state determined from the read done after receiving the activate command.

In response to receiving a pre-charge command, the desired new state is programmed into the memory bit (e.g., the opposite logic state to what was read in the activate phase) by applying appropriate electrical pulse(s) to the two cells of the memory cell pair that corresponds to the memory bit. For example, this programmed state will be kept by the memory array for a given retention time, even without power.

In one embodiment, a memory device receives an activate command, which starts an activate phase of operation. During the activate phase, a voltage ramp is applied to a memory cell pair (e.g., cells A, B) to detect a memory bit state. For example, bitlines used to select cells A and B are each charged at a fixed positive value. A voltage on a wordline used to select cells A and B is ramped to a negative voltage value. This sensing is non-destructive.

As soon as one of the two cells is determined to be switching (e.g., sinking current above a threshold as detected by a sense amplifier(s)), the voltages on the bitlines are reduced to avoid any additional switching. In particular, this is done to avoid having the other complementary one of the cells switch. In one example, each bitline voltage is grounded. The read data is stored in the read buffer (e.g., sense amplifier latch).

Next, as described above, read or write commands may be applied to the memory. If a write command is applied, a pre-charge command is next received. In one example, during the pre-charge phase, data in the sense amplifier latch is compared with data in the write buffer (WB) latch. This comparison is done to determine whether the memory bit will stay at the same state, or will be programmed to the new opposite state.

In the case in which the same state is detected, no programming occurs (this saves energy). In the case in which the opposite state is detected, appropriate programming pulses are applied to both of the cells A and B.

In one embodiment, the controller determines whether to refresh a portion of memory (e.g., a partition). In one example, the read of the memory cell pair is counted as an access to the partition that includes the memory cell pair. The controller can use an accumulated count of partition accesses that occur over time to determine when to perform a refresh of the partition.

In one example, the refresh is performed by page inversion. For example, during this refresh, a given refresh pulse (algorithm) can be applied by the memory controller to restore an inverse of the memory bit value of some or all memory cell pairs in the partition. An inversion bit is set and stored by the controller to keep track of the inversion status of the page stored in the partition. In one example, the page inversion is performed by reading the bits stored in a page in the memory array, then performing write operations to write the opposite data back to the memory array. The page inversion provides the benefit of drift cancellation.

Advantages achieved by at least some embodiments herein include providing memory that is non-volatile and persistent (in contrast to DRAM, which is not persistent). Another advantage is, for example, a memory device that provides page addressability in persistent memory that is significantly faster than prior memory devices. For example, the persistent memory has low latency due to use of a differential memory cell architecture, which provides larger signals when reading data from memory cells. For example, the use of a cross-point architecture for the memory provides deterministic access. Also, differential reading of memory cells provides low energy, non-destructive reads with a low raw bit error rate (RBER).

At least some embodiments herein can be implemented as memory devices using differential cells in low latency, deterministic applications, such as CXL (compute express link) attach Capacity Memory or Storage Class Memory. Storage Class Memory can provide improved performance (e.g., access time).

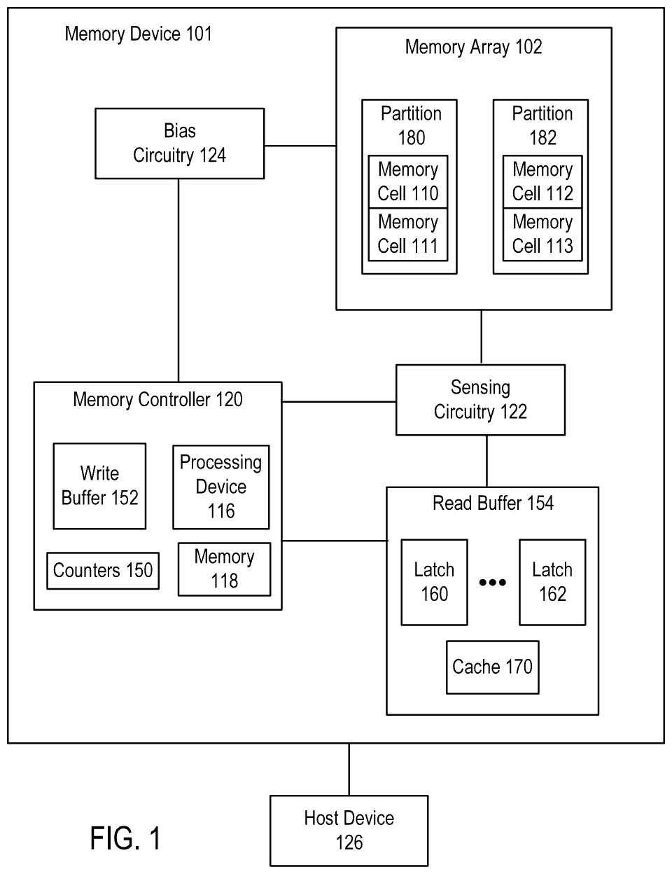

FIG. 1 shows a memory device 101 that stores single bits in a memory array 102 using memory cell pairs 110, 111 and 112, 113, in accordance with some embodiments. Memory cells 110, 111 are located in partition 180, and memory cells 112, 113 are located partition 182, for example. Memory cell pairs of memory array 102 may be located in various different partitions or tiles, or may be in the same partition or tile. Memory device 101 applies voltages to memory cells 110, 111 and/or 112, 113 when performing read, write, or other operations.

Memory device 101 has a memory controller 120 that controls the applied voltages. Memory controller 120 includes one or more processing devices 116, and memory 118. In one example, memory 118 stores firmware executed by processing device 116 to apply read or write voltages (e.g., a series of pulses).

Memory controller 120 can use bias circuitry 124 to generate voltages for applying read, write and other voltages. For example, bias circuitry 124 generates voltage waveforms for applying write voltages to memory cells 110, 111 and/or 112, 113 as part of programming operations.

In some cases, bias circuitry 124 is used to generate read voltages for read operations performed on memory array 102 (e.g., in response to a read command from host device 126). In one example, the read operation reads a memory cell pair (e.g., memory cells 110, 111). In one example, the read operation reads a codeword comprising bits (e.g., 128 bits). Each of the bits corresponds to a memory cell pair in memory cells 110. In one example, host device 126 is a controller on different chip or die than memory device 101, and memory device 101 is one of several memory die controlled by the host device 126.

In some embodiments, memory device 101 includes sensing circuitry 122, which is used to sense a state of each memory cell and/or memory cell pair in memory array 102. In one example, sensing circuitry 122 includes sense amplifiers used to detect a current caused by applying various voltages to memory cells or pairs in memory array 102. In one example, bias circuitry 124 applies a write voltage to memory cells 110, 111. In some cases, sensing circuitry 122 senses a current associated with the memory cells 110, 111 caused by applying the write voltage to determine if one of the cells 110, 111 has snapped.

In one example, if sensing circuitry 122 determines that the current for a memory cell or memory cell pair is greater than a fixed threshold (e.g., a predetermined level of current), then memory controller 120 determines that at least one of the memory cells has snapped, or that the memory cell is in a given logic state. In one example, sensing circuitry 122 additionally or alternatively determines an output based on a comparison of currents for two memory cells in a memory cell pair.

In one embodiment, memory cells 110, 111 and memory cells 112, 113 each correspond to cell pairs of different memory types (e.g., single level cell, or multi-level cell). In one embodiment, the material used to form a select device of each memory cell is different. The read or write voltage applied to memory cells 110, 111 corresponds to the material used to form memory cells 110, 111.

In one embodiment, memory controller 120 receives a write command from a host device 126. The write command is accompanied by data (e.g., user data of a user of host device 126) to be written to memory array 102. In response to receiving the write command, controller 120 initiates a write operation (e.g., the write command is followed by a pre-charge command when using a DRAM access protocol).

In one example, controller 120 uses write voltages (e.g., write pulses) to write a logic state to a memory cell pair, such as memory cells 110, 111 during a write operation. The write pulses may be applied by providing a first voltage to bitlines and providing a second voltage to a wordline to select the memory cells. Circuits coupled to access lines to which memory cells may be coupled may be used to provide the write voltages (e.g., access line drivers included in decoder circuits). The circuits may be controlled by internal control signals provided by a control logic (e.g., controller 120). The resulting voltage applied to each memory cell is the difference between the first and second voltages. The write pulses may be the same duration as read pulses in some embodiments. In some embodiments the duration is 10-50 ns. In some embodiments, the duration is 1-100 ns. In some embodiments, the duration is 1 ns to 1 microsecond. Writing to the memory cell may take the same time as reading the memory cell in some embodiments.

In one example, the polarity of the read or write pulses may be either a first polarity or a second polarity. For example, a read or write pulse may apply a voltage to a memory cell in a first polarity (e.g., bitline at +6V and wordline −2.5V).

In one example, after being accessed (e.g., selected), a memory cell or cell pair may be sensed by a sense component (e.g., sensing circuitry 122) to determine the stored state of the memory cell or memory cell pair. For example, a voltage may be applied to the memory cell(s) (using a wordline and bitline(s)) and the presence of a resulting current(s) may depend on the applied voltage and the threshold voltage and/or leakage characteristics of the memory cell. In some cases, more than one voltage may be applied. Additionally, if an applied voltage does not result in current flow (e.g., failure of cell to snap, or leakage current that is too low depending on read mode), other voltages (e.g., of increased magnitude, or ramping of wordline voltage) may be applied until an appropriate or suitable current is detected by the sense component.

By assessing the voltage(s) that resulted in current(s) flow, the stored logic state of the memory cells or cell pair may be determined. In some cases, the voltage may be ramped up in magnitude until a current flow is detected (e.g., leakage current(s) associated with a memory cell pair is sufficient for a logic state to be detected by a detector(s), or a memory cell in a pair turns on, switches on, conducts current, or becomes activated). In other cases, predetermined voltages may be applied sequentially until a suitable current(s) is detected.

In some cases, each memory cell (e.g., a PCM cell) includes a material that changes its crystallographic configuration (e.g., between a crystalline phase and an amorphous phase), which in turn, determines a threshold voltage of the memory cell to store information. In other cases, the memory cell includes a material that remains in a crystallographic configuration (e.g., an amorphous phase) that may exhibit variable threshold voltages to store information.

The sense component may include various transistors or amplifiers in order to detect and amplify a difference in signals from the memory cell(s). The detected logic state of the memory cell(s) may then be output through a column decoder as output. In some cases, the sense component may be part of a column decoder or a row decoder.

Read buffer 154 stores data read from memory array 102 by sensing circuitry 122. Read buffer 154 includes latches 160-162. In one example, each latch is integrated into a sense amplifier of sensing circuitry 122. In one example, each latch stores a logic state of a memory cell or memory cell pair as determined from sensing by sensing circuitry 122. In one example, this sensing is performed by one or more sense amplifiers. In one example, a sense amplifier is used to detect a logic state of memory cell 110 by detecting a current flow through memory cell 110. In one example, a sense amplifier used to detect a current flow associated with both memory cells 110, 111. In one example, differential current is detected.

In one embodiment, read buffer 154 includes cache 170. In one example, cache 170 stores one or more pages of data that have been read from memory array 102 in response to previously-received read commands. When controller 120 is reading partition 180, 182, controller 120 first checks to see if data to be read is stored in cache 170. If so, then a read access to memory 102 is not required. In some cases, this provides the advantage of reducing read disturb of memory cells in memory array 102.

Memory controller 120 includes write buffer 152. Data received by controller 120 with write commands received from host device 126 is stored in write buffer 152 prior to being written to memory array 102.

Memory controller 120 also includes counters 150. Counters 150 count the number of accesses made to each partition in memory array 102. For example, each access made to partition 180 or 182 is counted. In one embodiment, a separate counter 150 is used for each partition. Memory controller 120 uses a value of an accumulated count of partition accesses in each counter in order to determine whether to perform or refresh operation on that partition. In one embodiment, the decision to perform a refresh operation is made statistically. In one example, a random number generator is used to generate a random number that is used as part of a decision algorithm.

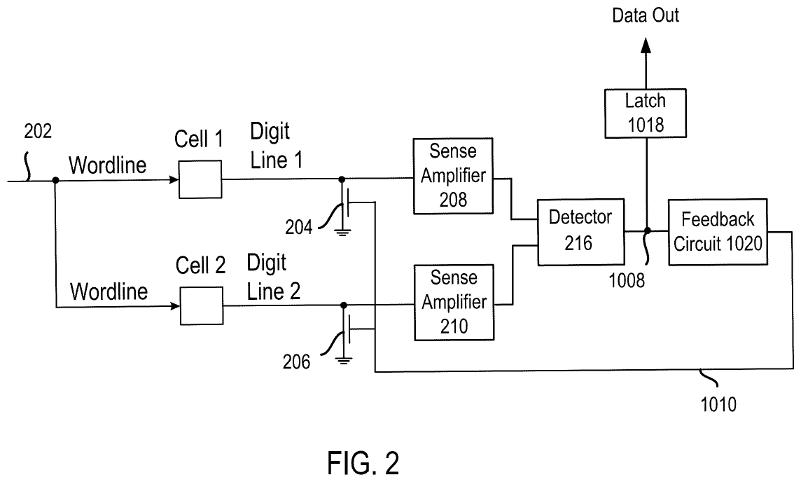

FIG. 2 shows detectors 212, 214 used to determine a logic state of a memory cell pair and a feedback circuit 1020 to control digit line (or bitline) voltages, in accordance with some embodiments. The memory cell pair includes cell 1 and cell 2. In one example, the memory cell pair is a pair of memory cells 110, 111 or 112, 113 of FIG. 1.

An output of the feedback circuit 1020 controls transistors 204, 206. The output is coupled to the gates of transistors 204, 206 to control a voltage on digit lines 1, 2.

A voltage is applied to digit lines 1, 2, and a voltage is applied to wordline 202 to select the memory cell pair for reading. Sense amplifiers 208 and 210 are coupled to digit lines 1, 2, which provide inputs to the sense amplifiers 208, 210. Based on currents and/or voltages sensed by each sense amplifier in the corresponding memory cell, each sense amplifier provides an output signal that is amplified. The output of each sense amplifier 208, 210 is provided as an input to detector 216. In other embodiments, a single sense amplifier can be coupled to cells 1, 2 and an output from the single sense amplifier is provided to detector 216.

The output 1008 of detector 216 corresponds to a detected logic state of the memory cell pair. For example, output 1008 can have a value of logic zero, or a value of logic one. The value of output 1008 is the data stored in the memory cell pair. This stored data is latched by latch 1018 and read by a controller as data output from the memory array.

In one embodiment, the outputs of sense amplifiers 208, 210 are provided to detector 216 as logic states of each memory cell such as 01 or 10 as a result from a read operation that reads the memory cell pair. The data out value for a logical bit corresponding to the memory cell pair is latched by latch 1018 in response to completion of the read of the memory cell pair. In one example, the data out value for the logical bit is one of numerous bits of a codeword being read by a controller in response to a read command (e.g., an activate command followed by a read command). In one example, the read command is received from a host device.

In one embodiment, each memory cell pair of multiple pairs (e.g., 128 pairs for 128 bits) is read by respective sense amplifiers 208, 210 and detectors 216. Each such memory cell pair has an output signal that is provided to a latch 1018 or similar. For example, the output signals are provided when reading a codeword or other block or logical unit from a portion of a memory array (e.g., from a partition). After the controller determines that a codeword has been fully read, the controller can take additional actions such as returning a data value or result to a host device in reply to a read command received from the host device.

In one embodiment, once the logic state of the memory cells or pair is determined by detector 216, output 1008 provides an input to feedback circuit 1020 that is used to reduce the digit line voltages. An output signal 1010 from feedback circuit 1020 controls transistors 204 and 206 to reduce voltages on digit lines 1, 2. In one example, transistors 204, 206 are n-type MOS pull-down devices.

The control to reduce the voltages on digit lines 1, 2 by feedback circuit 1020 avoids memory cells 1, 2 from any further switching during the read operation. In one example, feedback circuit 1020 includes one or more logic gates and/or inverters.

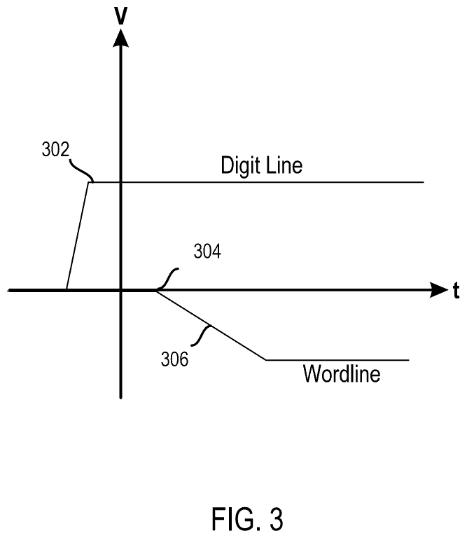

FIG. 3 shows exemplary digit line (or bitline) and wordline voltages applied to a memory cell pair during a read operation, in accordance with some embodiments. In one embodiment, voltages are applied to the wordline and digit lines using wordline and digit line drivers. In one example, these drivers are part of bias circuitry 124.

As illustrated, a voltage applied to each digit line for a memory cell pair is initially increased to a voltage 302. In one example, the voltage 302 is maintained at a fixed value during the read operation.

As illustrated, a voltage applied to the wordline starts at an initial value 304. In one example, initial value 304 is ground or a negative voltage (e.g., of a magnitude just below the E1 edge of a SET distribution). During the read operation, a controller ramps the voltage applied to the wordline using a ramp 306. Ramp 306 increases the magnitude of the voltage applied to the wordline. In the illustrated example, ramp 306 makes the voltage applied to the wordline more negative. As the voltage is ramped, the voltage across each of the memory cells in a memory cell pair increases.

In one example, voltage 302 is a positive voltage applied to digit lines 1, 2 of FIG. 2. Voltage 304 and ramp 306 (increasing negative voltage) are applied to wordline 202. Once the memory cell pair is read, ramp 306 is stopped by a controller. The controller may determine the end of the read based on an output of feedback circuit 1020 and/or the output 1008 of detector 216.

The gates of transistors 204, 206 are controlled to reduce the voltage on the digit lines 1, 2 to avoid switching of the one of the memory cells 1, 2 that has not yet switched. In one example, transistors 204, 206 are n-type MOS devices having one current terminal connected to the digit line, and another current terminal connected to a negative voltage source or ground.

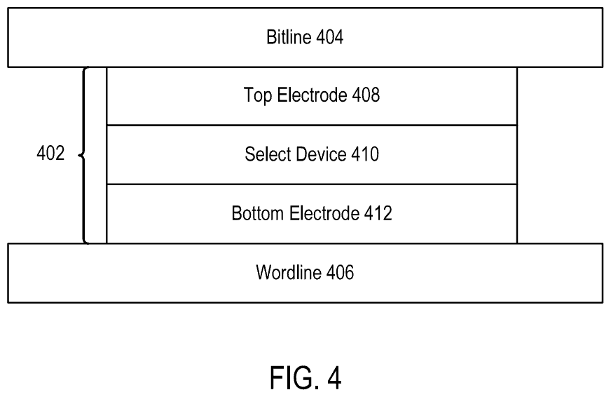

FIG. 4 shows an example of a memory cell 402 that includes a select device, in accordance with some embodiments. The memory cell 402 is an example of memory cell 110, 111. In one example, the memory cell is cell 1 or 2 of FIG. 2. In one example, select device 410 includes a chalcogenide.

Top electrode 408 conductively connects select device 410 to digit line or bitline 404, and bottom electrode 412 conductively connects select device 410 to wordline 406. In one example, electrodes 408, 412 are formed of a carbon material.

In one example, select device 410 includes a chalcogenide (e.g., chalcogenide material and/or chalcogenide alloy). Threshold voltage properties of the select device may be based on the voltage polarities applied to the memory cell.

In one example, a logic state may be written to memory cell 402, which may correspond to one or more bits of data. A logic state may be read from or written to the memory cell by applying voltages of different polarities at different voltage and/or current magnitudes. The reading and writing protocols may take advantage of different threshold voltages of the select device that result from the different polarities.

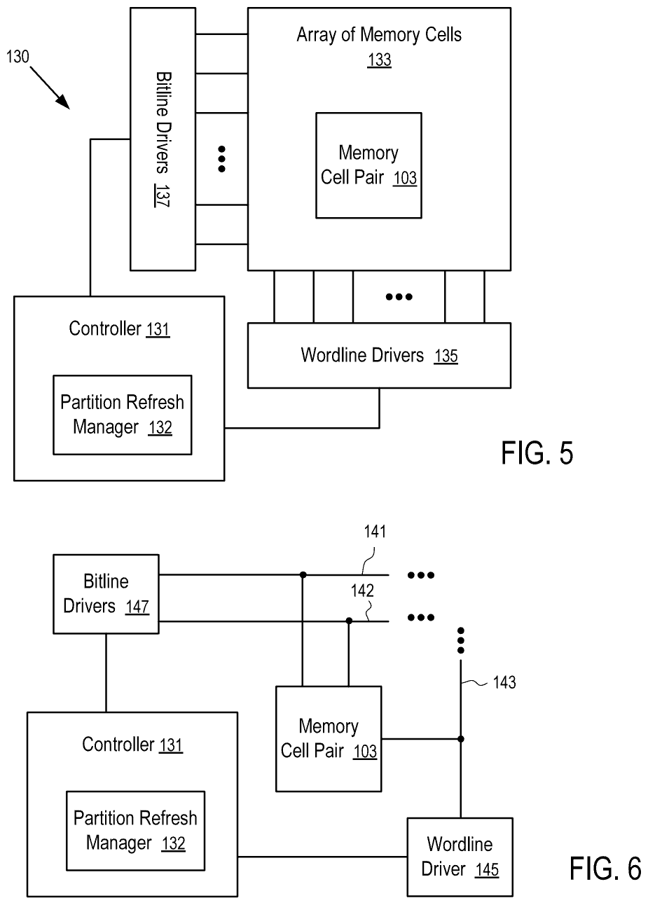

FIG. 5 shows a memory device 130 configured with a partition refresh manager 132 according to one embodiment. Memory device 130 is an example of memory device 101. In FIG. 5, the memory device 130 includes an array 133 of memory cell pairs, such as a memory cell pair 103. In one example, an array 133 can be referred to as a tile (or multiple tiles), and a memory device (e.g., 130) can have one or more tiles. Different tiles can be operated in parallel in a memory device (e.g., 130).

For example, the memory device 130 illustrated in FIG. 5 can have a cross-point memory having at least the array 133 of memory cell pairs (e.g., 103). In another example, the memory device 130 illustrated in FIG. 5 can have a 3D vertical architecture having at least the array 133 of memory cell pairs (e.g., 103).

In some implementations, the cross-point memory uses memory cells that have an element (e.g., a sole element) acting both as a selector device and a memory device. For example, the memory cell can use a single piece of alloy with variable threshold capability. The read/write operations of such a memory cell can be based on thresholding the memory cell while inhibiting other cells in sub-threshold bias, in a way similar to the read/write operations for a memory cell having a first element acting as a selector device and a second element acting as a phase-change memory device that are stacked together as a column. A selector device usable to store information can be referred to as a selector/memory device.

The memory device 130 of FIG. 5 includes a controller 131 that operates bitline drivers 137 and wordline drivers 135 to access the individual memory cells (e.g., cells of pair 103) in the array 133. For example, each memory cell in the array 133 can be accessed via voltages driven by a pair of a bitline driver 147 and a wordline driver 145, as illustrated in FIG. 6.

The controller 131 includes a partition refresh manager 132 configured to implement a process that performs a refresh of memory cells in memory array 133 as described herein. The partition refresh manager 132 can be implemented, for example, via logic circuits and/or microcodes/instructions.

In one example, the partition refresh manager 132 controls voltages applied to digit line drivers and a wordline driver for programming a memory cell pair to an opposite state (e.g., as part of a page inversion). The partition refresh manager 132 determines actions to take based on a count of accesses to various memory cells.

FIG. 6 shows a memory cell pair 103 with bitline drivers 147 and wordline driver 145 configured to apply voltages (e.g., pulses) to the memory cell pair 103 according to one embodiment. For example, the memory cell pair 103 can be a typical memory cell pair 103 in the memory cell array 133 of FIG. 6.

The bitline drivers 147 and the wordline driver 145 of FIG. 6 are controlled by controller 131 to selectively apply one or more voltages to each memory cell of the pair 103 (e.g., during a read operation). The bitline drivers 147 and the wordline driver 145 can apply voltages of different polarities on the memory cell pair 103.

For example, in applying one polarity of voltage (e.g., positive polarity), each bitline driver 147 drives a positive voltage relative to the ground on bitlines 141, 142; and the wordline driver 145 drives a negative voltage relative to the ground on a wordline 143.

In applying the opposite polarity of voltage (e.g., negative polarity), each bitline driver 147 drives a negative voltage on the bitlines 141, 142; and the wordline driver 145 drives a positive voltage on the wordline 143.

Each memory cell in pair 103 is subjected to the voltage difference between the voltage driven by the respective bitline driver 147 on the bitline 141, 142 and the voltage driven by the wordline driver 145 on the wordline 143.

In general, when the voltage driven by the bitline driver 147 is higher than the voltage driven by the wordline driver 145, the memory cell is subjected to a voltage in one polarity (e.g., positive polarity); and when the voltage driven by the bitline driver 147 is lower than the voltage driven by the wordline driver 145, the memory cell is subjected to a voltage in the opposite polarity (e.g., negative polarity).

In some implementations, the memory cell is a self-selecting memory cell implemented using a selector/memory device. The selector/memory device has a chalcogenide (e.g., chalcogenide material and/or chalcogenide alloy). For example, the chalcogenide material can include a chalcogenide glass such as, for example, an alloy of selenium (Se), tellurium (Te), arsenic (As), antimony (Sb), carbon (C), germanium (Ge), and silicon (Si). A chalcogenide material can primarily have selenium (Se), arsenic (As), and germanium (Ge) and be referred to as SAG-alloy. SAG-alloy can include silicon (Si) and be referred to as SiSAG-alloy. In some embodiments, the chalcogenide glass can include additional elements such as hydrogen (H), oxygen (O), nitrogen (N), chlorine (CI), or fluorine (F), each in atomic or molecular forms.

In one embodiment, the selector/memory device has a top side and a bottom side. A top electrode is formed on the top side of the selector/memory device for connecting to a bitline 141, 142, and a bottom electrode is formed on the bottom side of the selector/memory device for connecting to a wordline 143. For example, the top and bottom electrodes can be formed of a carbon material. For example, a chalcogenide material of the memory cell can take the form of a crystalline atomic configuration or an amorphous atomic configuration. The threshold voltage of the memory cell can be dependent on the ratio of the material in the crystalline configuration and the material of the amorphous configuration in the memory cell. The ratio can change under various conditions (e.g., having currents of different magnitudes and directions going through the memory cell).

A self-selecting memory cell, having a selector/memory device, can be programmed to have a threshold voltage window. The threshold voltage window can be created by applying programming pulses with opposite polarity to the selector/memory device. For example, the memory cell can be biased to have a positive voltage difference between two sides of the selector/memory device and alternatively, or to have a negative voltage difference between the same two sides of the selector/memory device. When the positive voltage difference is considered in positive polarity, the negative voltage difference is considered in negative polarity that is opposite to the positive polarity. Reading can be performed with a given/fixed polarity.

For example, to program the voltage threshold of the memory cell, a bitline driver 147 and the wordline driver 145 can drive a pulse of voltage onto the memory cell in one polarity (e.g., positive polarity) to snap the memory cell such that the memory cell is in a conductive state. While the memory cell is conductive, the bitline driver 147 and the wordline driver 145 continue driving the programming pulse to change the threshold voltage of the memory cell towards a voltage region that represents the data value(s) to be stored in the memory cell.

The array of memory cells 133 can be configured in an integrated circuit having a plurality of decks of memory cells. Each deck can be sandwiched between a layer of bitlines, a layer of wordlines; and the memory cells in the deck can be arranged in an array 133. A deck can have one or more arrays or tiles. Adjacent decks of memory cells may share a layer of bitlines (e.g., 141, 142) or a layer of wordlines (e.g., 143). Bitlines are arranged to run in parallel in their layer in one direction; and the wordlines are arranged to run in parallel in their layer in another direction orthogonal to the direction of the bitlines. Each of the bitlines is connected to a row of memory cells in the array; and each of the wordlines is connected to a column of memory cells in the array. Bitline drivers 137 are connected to bitlines in the decks; and wordline drivers 135 are connected to wordlines in the decks. Thus, a typical memory cell is connected to a bitline driver 147 and a wordline driver 145.

In some embodiments, the threshold voltage of a typical memory cell is configured to be sufficiently high such that when only one of its bitline driver 147 and wordline driver 145 drives a voltage in either polarity while the other voltage driver holds the respective line to the ground, the magnitude of the voltage applied across the memory cell is insufficient to cause the memory cell to become conductive. Thus, addressing the memory cell can be performed via both of its bitline driver 147 and wordline driver 145 driving a voltage in opposite polarity relative to the ground for operating/selecting the memory cell. Other memory cells connected to the same wordline driver 145 can be de-selected by their respective bitline drivers holding the respective bitlines to the ground; and other memory cells connected to the same bitline driver can be de-selected by their respective wordline drives holding the respective wordlines to the ground.

A group of memory cells connected to a common wordline driver 145 can be selected for parallel operation by their respective bitline drivers (e.g., 147) driving up the magnitude of voltages in one polarity while the wordline driver 145 is also driving up the magnitude of a voltage in the opposite polarity. Similarly, a group of memory cells connected to a common bitline driver 147 can be selected for parallel operation by their respective wordline drivers (e.g., 145) driving voltages in one polarity while the bitline driver 147 is also driving a voltage in the opposite polarity.

At least some examples are disclosed herein in reference to a cross-point memory having self-selecting memory cells. Other types of memory cells and/or memory can also be used. For example, memory cells each having a selector device and a phase-change memory device can also be used in at least some embodiments. Additionally or alternatively, the memory can have a different architecture, such as a 3D vertical architecture.

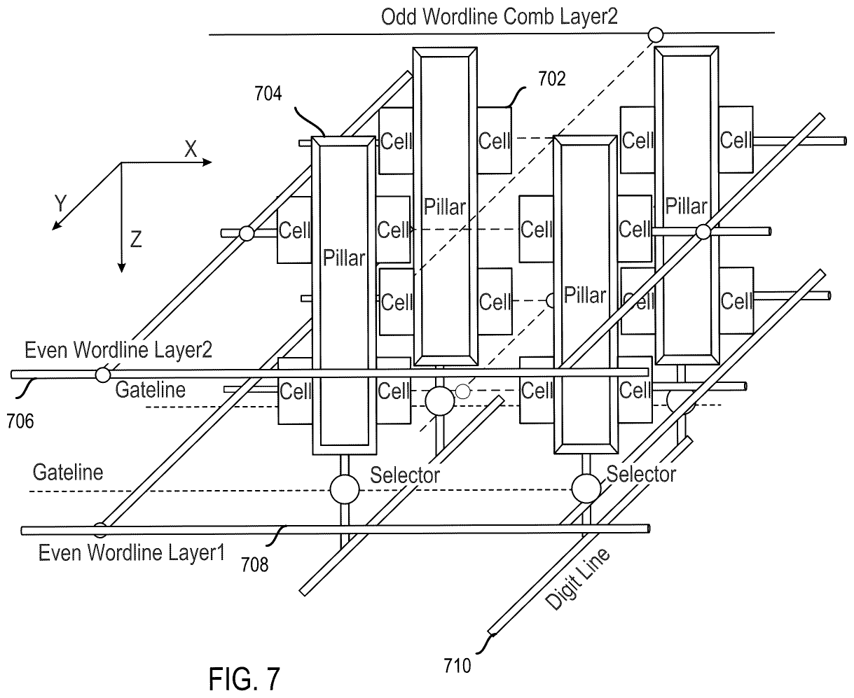

FIG. 7 shows an exemplary three-dimensional memory array structure, in accordance with some embodiments. The memory array and memory cells described herein are not limited to use in a planar architecture (e.g., with cells at crossing of WLs and BLs on different levels). Instead, the approach also can be used for vertical architectures (e.g., BL pillars crossing WL planes).

An example of a vertical architecture that can be used with embodiments described in this disclosure is illustrated in FIG. 7. As illustrated, a memory array includes memory cells 702. Each memory cell 702 can be selected using a wordline (e.g., 706 or 708) and a digit line (e.g., 710). Memory cells 702 are an example of memory cells 110, 111 of FIG. 1.

In one embodiment, each wordline extends in one of a plurality of horizontal planes of wordlines 706, 708 stacked vertically above a semiconductor substrate (not shown). Each digit line (e.g., 710) includes a pillar 704. Each pillar 704 extends vertically away from the semiconductor substrate. Each memory cell 702 is located on sides of one of pillars 704.

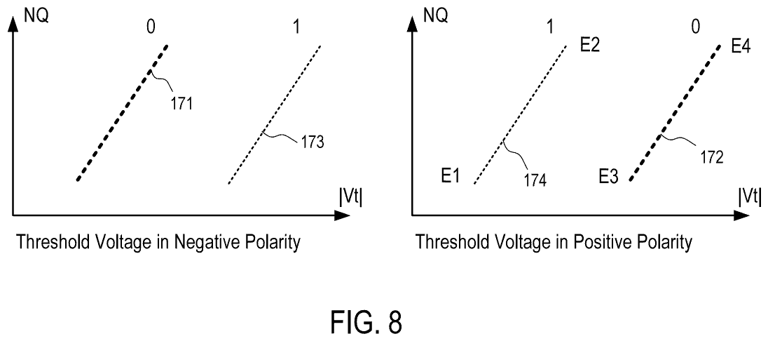

FIG. 8 shows an exemplary normal quantile (NQ) plot representing the statistical distributions (e.g., 171-174) of threshold voltages of memory cells. In one example, the memory cells are memory cells 110, 111 or 112, 113 of FIG. 1. When a probability distribution (e.g., 171) of threshold voltages programmed in a region is a normal distribution (also known as Gaussian distribution), its normal quantile (NQ) plot is seen as aligned on a straight line (e.g., distribution 171).

A self-selecting memory cell (e.g., 110) can have a threshold voltage in negative polarity and a threshold voltage in positive polarity. When a voltage applied on the memory cell 110 in either polarity is increased in magnitude up to its threshold voltage in the corresponding polarity, the memory cell (e.g., 110) snaps from a non-conductive state to a conductive state.

The threshold voltage of a memory cell 110 in negative polarity and the threshold voltage of the memory cell 110 in positive polarity can have different magnitudes. Memory cells programmed to have large magnitudes in threshold voltages in positive polarity can have small magnitudes in threshold voltages in negative polarity; and memory cells programmed to have small magnitudes in threshold voltages in positive polarity can have large magnitudes in threshold voltages in negative polarity.

For example, a memory cell can be programmed to have a small magnitude in threshold voltage according to distribution 174 in the positive polarity to represent a value (e.g., one); and as a result, its threshold voltage has a large magnitude according to distribution 173 in the negative polarity to represent the same value (e.g., one). Alternatively, the memory cell can be programmed to have a large magnitude in threshold voltage according to distribution 172 in the positive polarity to represent another value (e.g., zero); and as a result, its threshold voltage has a smaller magnitude according to distribution 171 in the negative polarity to represent the same value (e.g., zero).

Thus, to determine whether a memory cell 110 is storing the one value (e.g., one) or the other value (e.g., zero), a controller can read the memory cell 110 in either the positive polarity or the negative polarity. If the threshold voltage of the memory cell 110 has a large magnitude according to distribution 172 in the positive polarity, it stores the other value (e.g., zero); otherwise, it stores the one value (e.g., one). Similarly, if the threshold voltage of the memory cell 110 has a large magnitude according to distribution 173 in the negative polarity, it stores the one value (e.g., one); otherwise, it stores the other value (e.g., zero).

For purposes of illustration, the so-called E1, E2, E3, and E4 edges of the distributions 172, 174 are indicated in FIG. 8. For example, the E4 edge of distribution 172 corresponds to the E4 edge of the reset distribution.

The threshold voltage distributions of memory cells may change after a read. For example, in the positive polarity, a read can cause the high magnitude distribution 172 to shift downward, and/or the low magnitude distribution 174 to shift downward.

Similarly, in negative polarity, the read can cause the high magnitude distribution 173 to shift downward, and/or the low magnitude distribution 171 to shift downward.

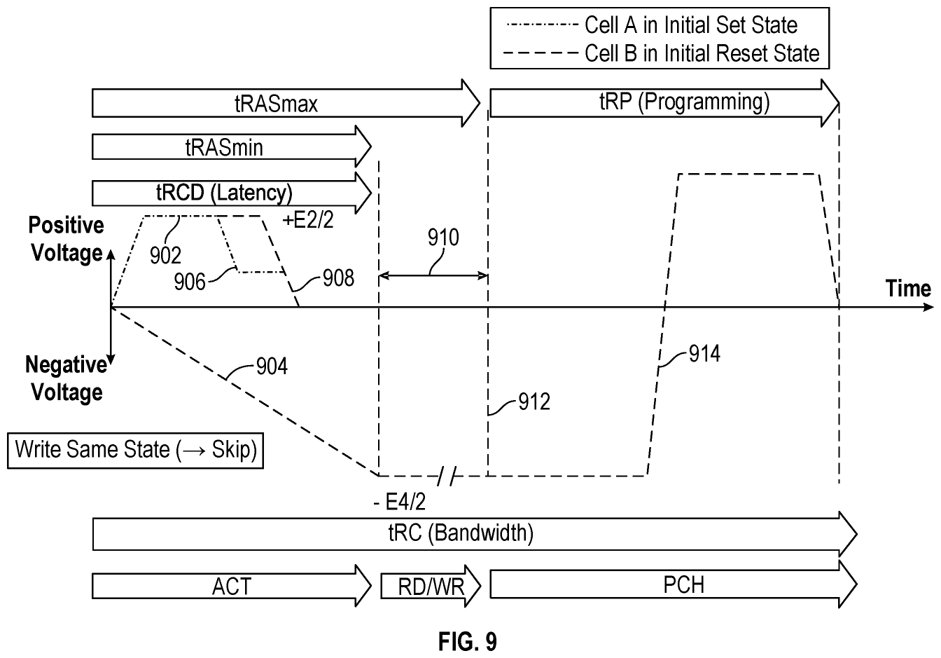

FIG. 9 shows exemplary timings associated with read and write operations for a memory cell pair in which the write operation is for a same state, in accordance with some embodiments. In one example, the memory cell pair is memory cells 110, 111 or 112, 113 of FIG. 1.

Voltages are applied to a wordline and bitlines to select exemplary memory cells A, B, as illustrated. Cell A is initially in a SET state, and cell B is initially in a RESET state. In one example, the voltages are applied by bias circuitry 124 of FIG. 1. It should be noted that voltages of the opposite polarities to that illustrated can be applied in other embodiments.

A fixed positive voltage 902 is applied to each bitline. A negative voltage ramp 904 is applied to the wordline. These voltages are applied, for example, in response to a controller receiving an activate command (ACT).

In one example, the voltage 902 is a voltage corresponding to one half of the E2 edge threshold voltage (+E2/2) of the probability threshold distribution for memory cells of the same type as the memory cell pair. In one example, voltage ramp 904 decreases the wordline voltage to one half of the E4 edge threshold voltage (−E4/2) of the probability threshold distribution for memory cells of the same type as the memory cell pair. In one example, these E2 and E4 edges are illustrated in FIG. 8 discussed above.

Cell A is the first of the two cells to switch (e.g., threshold or snap), which corresponds to a voltage drop 906, as illustrated. The switching of cell A is detected, for example, by a sense amplifier. After the switching is detected, the voltages 908 applied to the bitlines are reduced (e.g., as described for FIG. 2 above). In the illustrated example, the voltages 908 are reduced to ground.

In one embodiment, timings for the voltages applied to the bitlines and wordlines is made consistent with timings corresponding to an access protocol for a DRAM. Exemplary access protocol timings are indicated as tRC (row cycle), tRCD (row column delay), tRASmin (row address strobe minimum), tRASmax (row address strobe maximum), and tRP (pre-charge time for programming).

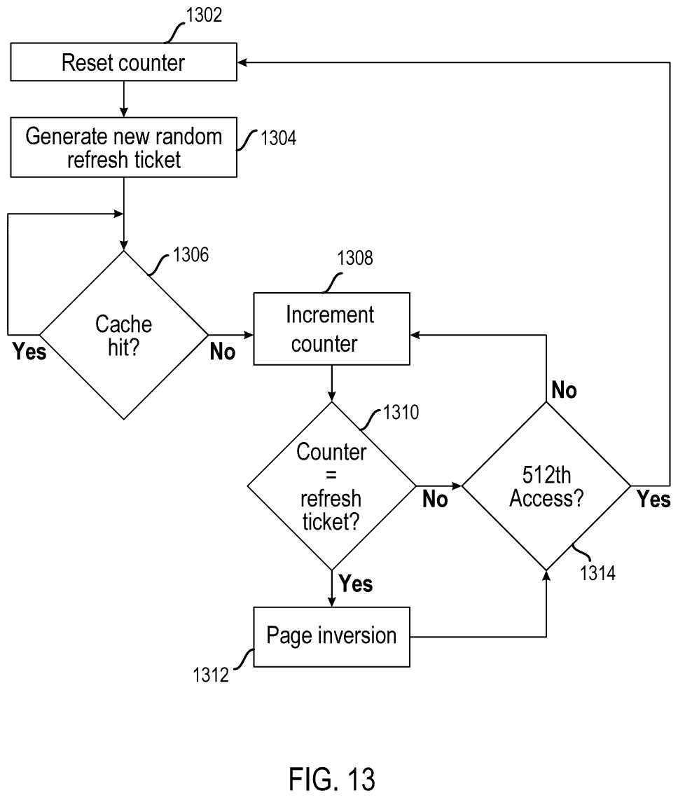

As mentioned above, memory cells in DRAMs must be periodically refreshed. In contrast, for the memory device using the illustrated memory cell pairs, no such refresh is necessary. A DRAM performs its refresh in time period 910 (e.g., between tRASmin and tRASmax). According to embodiments as described herein, time period 910 can instead be used for periodically refreshing memory cells at times as determined for performing refresh operations (e.g., as determined by a controller as discussed herein) (e.g., method of FIG. 13).

In one embodiment, because the memory cell pairs provide persistent memory storage, time period 910 can be arbitrarily set to a duration as desired. In one example, time period 910 varies from one read access to another based on a context of operation of a memory device as determined by a controller. The time period 910 can correspond to determinations of the needed extent and/or type of refresh operations by the controller (e.g., which and/or what number of partitions need refreshing), which can be the basis for setting the time period 910.

If a read command (RD) is received, then data read from the memory cell pair is provided to a host device. If a write command (WR) is received, then data received with the write command is written to memory. In one example, as illustrated, the data bit corresponding to the illustrated memory cell pair as stored in the write buffer latch is compared to the data bit read from the sense amplifier latch. The data bit to be written is the same as the read data bit. In other words, the memory cell pair can stay in the same logic state. Therefore, for the illustrated memory cell pair, no programming is done and no voltages are applied to the bitlines. Instead, the bitlines remain at ground.

It should be noted, however, that other memory cell pairs on the same wordline will be programmed starting at time 912 (e.g., in response to receiving a pre-charge (PCH) command). Thus, a programming voltage profile 914 is applied to the wordline. In one embodiment, an exception to this would be a case where all memory cell pairs on a wordline are already determined to be at the same state to be written. In that case, the wordline can simply be discharged.

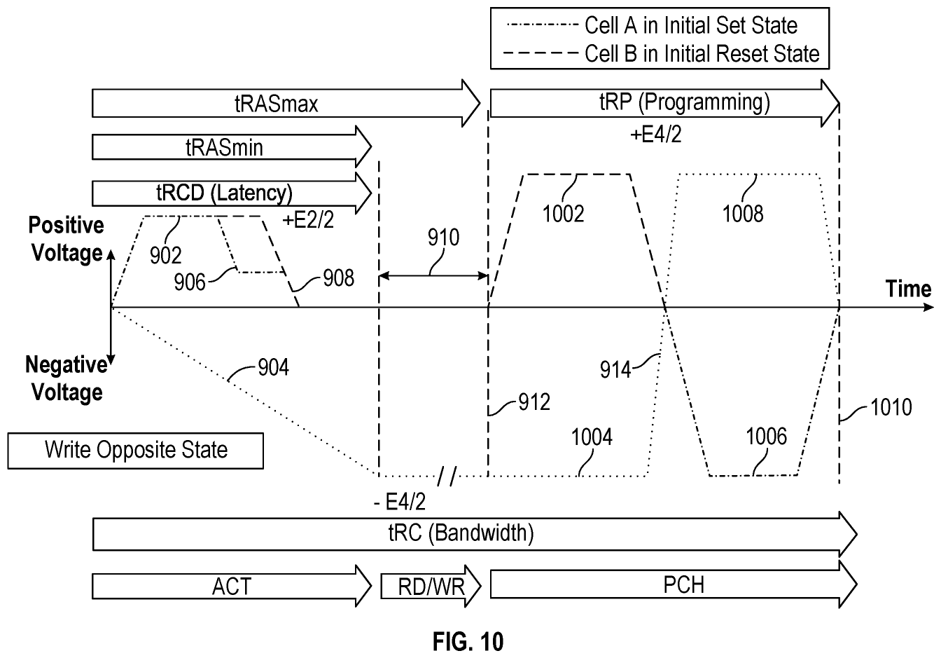

FIG. 10 shows exemplary timings associated with read and write operations for a memory cell pair in which the write operation is for an opposite state, in accordance with some embodiments. FIG. 10 illustrates the case for another memory cell pair on the same wordline as the memory cell pair of FIG. 9 above. In this case, in response to receiving a write command, it is determined that data to be written is the opposite to the data read by the sense amplifier. In other words, the logic state of the illustrated memory cell pair needs to be changed to an opposite state.

As illustrated, at time 912, in response to receiving a pre-charge command, the memory cell pair is programmed. The programming is performed by applying two write pulses.

The first pulse programs memory cell B to a SET state. Voltage 1002 is applied to the bitline that selects cell B. In one example, the voltage applied is one half of the threshold voltage corresponding to the E4 edge (+E4/2). Voltage 1004 is applied to the wordline used to select cell B. In one example, voltage 1004 is one half of the threshold voltage for the E4 edge (−E4/2), as discussed above.

The second pulse programs memory cell A to a RESET state. The voltage on the wordline is changed to an opposite polarity. Voltage 1008 is applied to the wordline during the second pulse programming. In one example, voltage 1008 is the same as voltage 1002 (e.g., +E4/2). Voltage 1006 (e.g., −E4/2) is applied to the bitline that selects memory cell A. Voltage 1006 is of an opposite polarity to voltage 1002 applied to the other bitline in the first pulse.

The programming phase ends at time 1010. In one embodiment, a controller sends a signal to the host device indicating completion of the programming for the wordline.

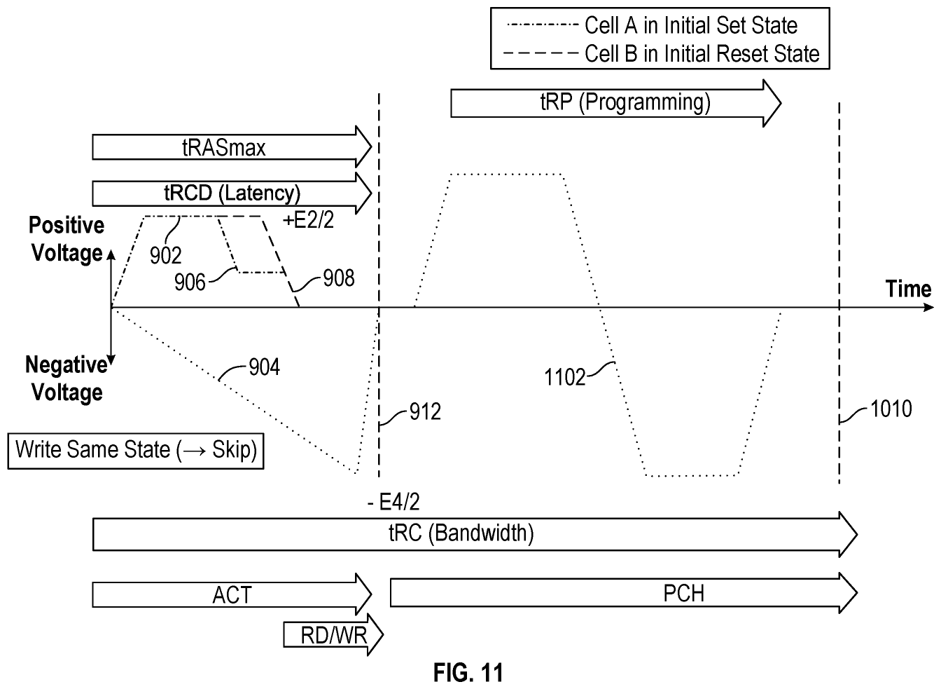

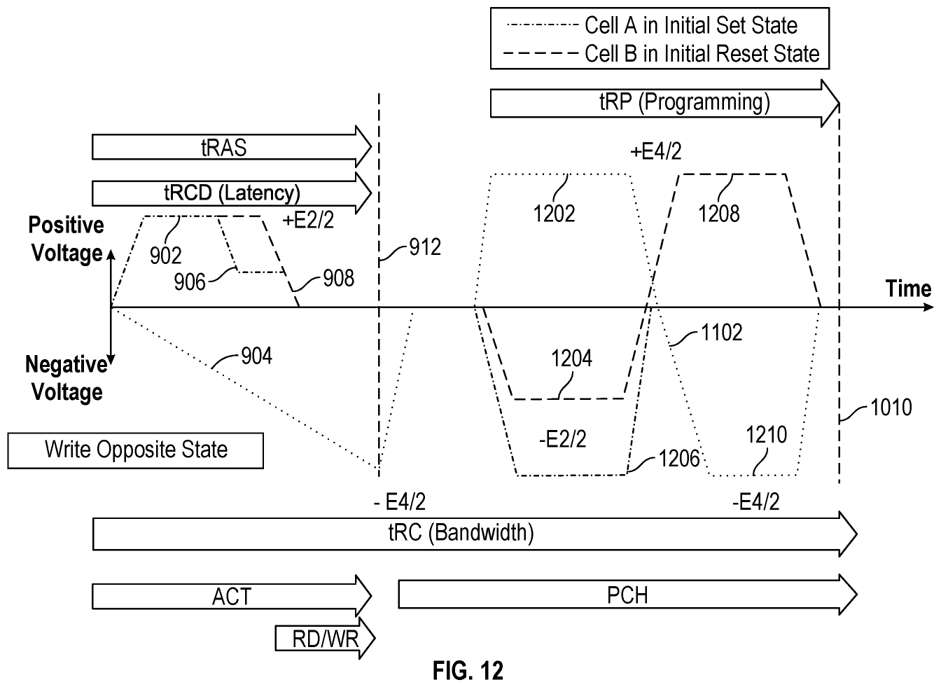

FIG. 11 shows exemplary timings associated with read and write operations for a memory cell pair in which the write operation uses additional drift cancellation and the write operation is for a same state, in accordance with some embodiments. The reading and programming of the memory cell pair (e.g., cells A, B) as illustrated for FIGS. 11 and 12 is similar to that as described for FIGS. 9 and 10 above. However, the programming voltage profile 1102 for the wordline includes an additional change or flip in polarity so that drift cancellation can be implemented for a second one of the cells A, B. Drift cancellation for the first one of the cells occurs during the read.

For the memory cell pair illustrated here, a controller has determined that the read data is the same as the data to be written. Therefore, no voltages are applied to the bitlines for the illustrated memory cell pair during the programming phase. However, voltage profile 1102 is applied to the wordline so that any other memory cell pairs on the same wordline can be programmed during the programming phase illustrated.

FIG. 12 shows exemplary timings associated with read and write operations for another memory cell pair (on the same wordline as for FIG. 11 above) in which the write operation uses additional drift cancellation and is for an opposite state, in accordance with some embodiments. FIG. 12 illustrates the case for another memory cell pair on the same wordline as the memory cell pair of FIG. 11 above. In this case, in response to receiving a write command, it is determined that the data to be written is the opposite to the data read by the sense amplifier. In other words, the logic state of the illustrated memory cell pair needs to be changed to an opposite state.

In the illustrated programming phase, programming is performed by applying two write pulses. It should be noted that in other embodiments, additional pulses may be applied and/or an order of pulses may be varied.

The first pulse programs memory cell A to a RESET state. Voltage 1206 is applied to the bitline that selects cell A. In one example, the voltage applied is one half of the threshold voltage corresponding to the E4 edge (−E4/2). The voltage 1202 on the wordline is changed to an opposite polarity as used during reading. Voltage 1202 is applied to the wordline used to select cell A. In one example, voltage 1202 is one half of the threshold voltage for the E4 edge (+E4/2).

During the first write pulse, voltage 1204 is applied to the bitline that selects memory cell B. In one example, voltage 1204 is one half of the threshold voltage corresponding to the E2 edge (−E2/2) of the threshold voltage probability distribution discussed above. Voltage 1204 is applied for drift cancellation for memory cell B. It should be noted that drift cancellation for memory cell A is accomplished by applying voltage 902 when reading memory cell A. Thus, drift cancellation is provided for each memory cell A, B.

The second pulse programs memory cell B to a SET state. The voltage 1210 on the wordline is changed to an opposite polarity as used during the first write pulse. Voltage 1210 is applied to the wordline during the second pulse programming. In one example, voltage 1210 is the same as voltage 1206 (e.g., −E4/2). Voltage 1208 (e.g., +E4/2) is applied to the bitline that selects memory cell B. Voltage 1208 is of an opposite polarity to voltage 1206 applied to the other bitline in the first pulse.

FIG. 13 shows a method for managing refresh operations for partitions of a memory array, in accordance with some embodiments. For example, the method of FIG. 13 can be implemented in the system of FIG. 1 by controller 120. In one example, the partitions to be refreshed are partitions 180, 182. In one example, the method is implemented by partition refresh manager 132.

The method of FIG. 13 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 13 is performed at least in part by one or more processing devices (e.g., controller 120 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 1302, a counter is reset. In one example, a counter is used to count partition accesses for each partition of a memory array. In one example, counters 150 are used to count partition accesses to partitions 180, 182.

At block 1304, a new random number is generated. In one example, the new random number is generated as a random refresh ticket. In one example, the random number is generated to be a value between 1 and a fixed number (e.g., 512).

At block 1306, a determination is made whether the current access to the partition is to access data that has been previously read and is stored in a cache. In one example, the cache is cache 170. If the data is already stored in the cache, then the counter is not incremented.

At block 1308, after determining that the data to be read is not stored in the cache, the counter is incremented.

At block 1310, a determination is made whether the counter is equal to the value of the random number that was generated at block 1304. In one example, the counter is compared to the refresh ticket.

At block 1312, if the counter equals the random number value, then data in the partition is refreshed. In one example, the refresh is performed by inversion of a page of data stored in the partition. In one example, the data stored in the page includes bits stored by memory cells 110, 111 and 112, 113.

At block 1314, if the counter does not equal the value of the random number, and a number of accesses to the partition is less than a fixed number (e.g., 512), then the counter is incremented again at block 1308 (for each access to the partition). In one embodiment, the fixed number (e.g., 512) used for comparison at block 1314 is the same fixed number (e.g., 512) used for defining the range of potential random numbers generated at block 1304.

At block 1314, if the number of accesses to the partition based on the counter is equal to the fixed number (e.g., 512), then the method proceeds to block 1302, where the counter is reset for counting future accesses to the partition. At block 1304, another new random number is generated.

In one embodiment, a refresh of a partition can be triggered by other events. In one example, partition refresh is triggered by a read failure. In one example, partition refresh is triggered by an indeterminate state read (e.g., both memory cells reading as logic one or logic zero).

In one embodiment, a memory device has a controller (e.g., 120, 131) configured to: determine to refresh a partition of a memory array that includes a first memory cell pair (cells A, B of FIGS. 10, 12); and in response to determining to refresh the partition, invert a logic state of first and second memory cells (e.g., cells A, B) of the first memory cell pair.

In one embodiment, data is read from the memory array in response to commands from a host device (e.g., 126), and the read data is provided to the host device within a read completion time; a read latency for reading data stored in the memory array is less than the read completion time; and the partition is refreshed within a time period (e.g., time period 910 of FIG. 10) starting after data is read from the memory array, and prior to the read completion time.

In one embodiment, the read latency corresponds to a row column delay time (e.g., tRCD), and the read completion time corresponds to a row cycle time (e.g., tRC).

In one embodiment, at least a portion of a page of data is stored in the partition, and inverting the logic state is performed as part of an inversion of the page.

In one embodiment, the memory device further comprises a counter configured to count each access to the partition, wherein determining to refresh the partition comprises: generating a random number; incrementing the counter on each access to the partition (e.g., block 1308); comparing a value of the counter to the random number; and determining that the value of the counter equals the random number.

In one embodiment, the buffer includes a cache configured to store data previously read from the memory array prior to a current access to the partition; and the counter is not incremented if data to be read for the current access will be read from the cache instead of from the memory array.

In one embodiment, when the counter reaches a threshold (e.g., 512 accesses at block 1314), the counter is reset and a new random number is generated; and the value of the counter is compared to the new random number on subsequent accesses to the partition.

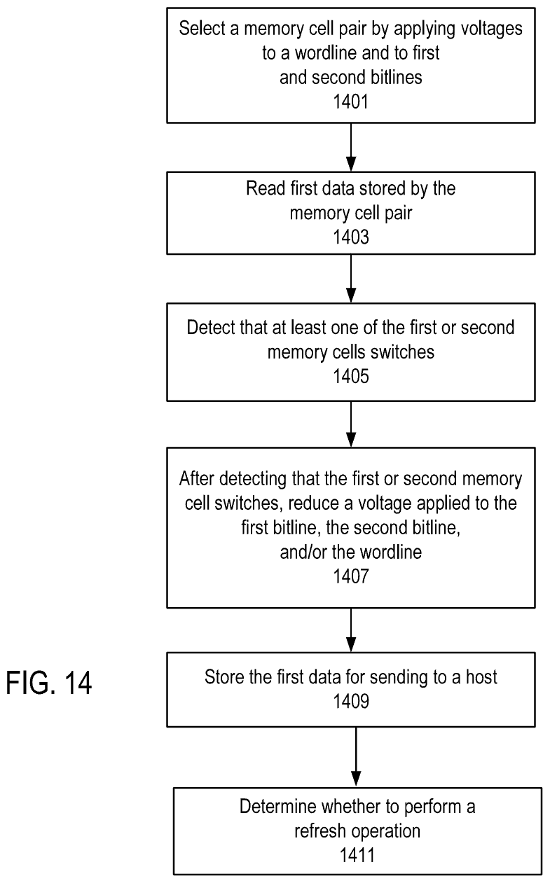

FIG. 14 shows a method for reading data stored in a memory cell pair and determining whether to perform a refresh operation, in accordance with some embodiments. For example, the method of FIG. 14 can be implemented in the system of FIG. 1.

The method of FIG. 14 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 14 is performed at least in part by one or more processing devices (e.g., controller 120 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 1401, a memory cell pair is selected by applying voltages to a wordline and to first and second bitlines (e.g., in response to receiving an activate command). In one example, the memory cell pair includes memory cells 112, 113. In one example, the wordline is wordline 202, and the bitlines are digit lines 1, 2 of FIG. 2.

At block 1403, first data stored by the memory cell pair is read. In one example, sensing circuitry 122 determines a logic state of a memory cell pair in memory array 102.

At block 1405, a detection is made that at least one of the first or second memory cells has switched. In one example, a sense amplifier determines that a current through memory cell 110 exceeds a threshold and has snapped. The sense amplifier sends a signal to a controller that indicates the detection has been made.

At block 1407, after detecting that the first or second memory cell has switched, a voltage applied to the first bitline, the second bitline, and/or the wordline is reduced. In one example, transistors 204 and 206 of FIG. 2 are turned on to reduce a voltage of digit lines 1, 2. In one example, a wordline is discharged to ground.

At block 1409, the first data is stored for sending to a host. In one example, data read from a memory cell pair is stored in latch 160.

At block 1411, a determination is made whether to perform a refresh operation. In one example, controller 120 executes a refresh process to count access partitions and statistically determine when to refresh partitions (e.g., using the method of FIG. 13).

In one embodiment, an apparatus comprises: a memory array (e.g., 102, 133) comprising memory cells arranged as memory cell pairs, each pair configured to store a logical bit; bias circuitry (e.g., 124) configured to select a first memory cell pair having first and second memory cells by applying voltages to a wordline and to first and second bitlines to select the first and second memory cells, wherein the bias circuitry is further configured to reduce a magnitude of at least one of the voltages on the first or second bitlines after at least one of the first or second memory cells switches; sensing circuitry (e.g., 122) configured to read first data stored by the first memory cell pair; and a buffer (e.g., 154) configured to store the read first data.

In one embodiment, the buffer includes a first latch (e.g., 160), and the apparatus further comprises: a second latch (e.g., write buffer 152) configured to store data to be written to the memory array; and a controller configured to: receive a write command with second data to be stored; in response to receiving the write command, store the second data in the second latch; compare the first and second data; determine, based on comparing the first and second data, that the second data is not stored in the memory array; and change a logic state for each of the first and second memory cells to store the second data.

In one embodiment, changing the logic state for the first and second memory cells is performed in response to receiving a pre-charge command.

In one embodiment, changing the logic state comprises applying, using the bias circuitry, at least one pulse to each of the first and second memory cells.

In one embodiment, the apparatus further comprises a controller configured to: receive an activate command; and in response to receiving the activate command, cause the sensing circuitry to read the first data by determining a logic state of the first memory cell pair.

In one embodiment, the controller is further configured to: after receiving the activate command, receive a read command; and in response to receiving the read command, retrieve the first data from the buffer.

In one embodiment, the first memory cell is selected using the wordline and the first bitline, and the second memory cell is selected using the wordline and the second bitline.

In one embodiment, the apparatus further comprises a controller configured to: determine that at least one of the first or second memory cells has switched; and in response to determining that at least one of the first or second memory cells has switched, cause the bias circuitry to reduce the magnitude of the voltages on the first and second bitlines.

In one embodiment, at least one of the first or second memory cells switches when the sensing circuitry is reading the first data stored by the first memory cell pair.

In one embodiment, the wordline voltage is applied as a ramp of increasing magnitude when reading the first data.

In one embodiment, the voltage applied to the first and second bitlines is of a first polarity; and the voltage applied to the wordline is of a second polarity opposite to the first polarity.

In one embodiment, the apparatus further comprises a controller configured to: receive a write command with second data to be stored in the memory array; and after receiving the write command, initiate a programming operation to change a logic state of the first and second memory cells to correspond to the second data.

In one embodiment, the first memory cell switches when the sensing circuitry reads the first data, and the programming operation comprises: applying a first programming pulse to program the second memory cell, wherein applying the first programming pulse comprises applying a voltage to the wordline at the second polarity; and applying a second programming pulse to program the first memory cell, wherein applying the second programming pulse comprises applying a voltage to the wordline at the first polarity.

In one embodiment, the second cell is programmed prior to programming the first cell.

In one embodiment, the first cell is programmed prior to programming the second cell.

In one embodiment, an apparatus comprises: a latch configured to store data for sending to a host; a memory array comprising memory cells arranged as memory cell pairs, each pair configured to store a logical bit; and a controller configured to: receive a first command from a host that initiates a read operation; select, using access lines, a first memory cell pair having first and second memory cells, wherein the first memory cell pair is located in a first partition of the memory array, and the first memory cell pair stores first data; access the first partition to read the first data; store the first data in the latch; in response to accessing the first partition, determine whether to perform a refresh operation; and in response to determining to perform the refresh operation, refresh the first partition.

In one embodiment, the first command is an activate command, the controller is further configured to receive a read command from the host, and the first data is sent to the host in response to receiving the read command.

In one embodiment, the first partition is refreshed after reading the first data and prior to completion of the read operation.

In one embodiment, the controller is further configured to: receive a write command from the host with second data to be stored; and store the second data by changing a logic state of the first and second memory cells.

In one embodiment, the controller is further configured to receive a pre-charge command after receiving the write command, and the second data is stored in response to receiving the pre-charge command.

In one embodiment, the access lines include first and second bitlines and a wordline.

In one embodiment, a first voltage is applied to the first and second bitlines to read the first data; and a second voltage of a greater magnitude than the first voltage is applied to the first and second bitlines to change the logic state of the first and second memory cells.

In one embodiment, the controller is further configured to reduce a magnitude of a voltage on at least one of the access lines after at least one of the first or second memory cells switches.

In one embodiment, a method comprises: in response to receiving a command from a host, selecting a first memory cell pair having first and second memory cells by applying voltages to a wordline and to first and second bitlines; reading first data stored by the first memory cell pair; while reading the first data, detecting that at least one of the first or second memory cells switches; after detecting that at least one of the first or second memory cells switches, reducing a magnitude of a voltage applied to at least one of the first bitline, the second bitline, or the wordline; and storing the read first data for sending to the host.

In one embodiment, a first partition of the memory array is accessed when reading the first data, and the method further comprises: determining whether to perform a refresh operation for the first partition; and in response to determining to perform the refresh operation, refresh at least the first memory cell pair.

The disclosure includes various devices which perform the methods and implement the systems described above, including data processing systems which perform these methods, and computer-readable media containing instructions which when executed on data processing systems cause the systems to perform these methods.

The description and drawings are illustrative and are not to be construed as limiting. Numerous specific details are described to provide a thorough understanding. However, in certain instances, well-known or conventional details are not described in order to avoid obscuring the description. References to one or an embodiment in the present disclosure are not necessarily references to the same embodiment; and, such references mean at least one.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

In this description, various functions and/or operations may be described as being performed by or caused by software code to simplify description. However, those skilled in the art will recognize what is meant by such expressions is that the functions and/or operations result from execution of the code by one or more processing devices, such as a microprocessor, Application-Specific Integrated Circuit (ASIC), graphics processor, and/or a Field-Programmable Gate Array (FPGA). Alternatively, or in combination, the functions and operations can be implemented using special purpose circuitry (e.g., logic circuitry), with or without software instructions. Embodiments can be implemented using hardwired circuitry without software instructions, or in combination with software instructions. Thus, the techniques are not limited to any specific combination of hardware circuitry and software, nor to any particular source for the instructions executed by a computing device.

While some embodiments can be implemented in fully functioning computers and computer systems, various embodiments are capable of being distributed as a computing product in a variety of forms and are capable of being applied regardless of the particular type of computer-readable medium used to actually effect the distribution.

At least some aspects disclosed can be embodied, at least in part, in software. That is, the techniques may be carried out in a computing device or other system in response to its processing device, such as a microprocessor, executing sequences of instructions contained in a memory, such as ROM, volatile RAM, non-volatile memory, cache or a remote storage device.

Routines executed to implement the embodiments may be implemented as part of an operating system, middleware, service delivery platform, SDK (Software Development Kit) component, web services, or other specific application, component, program, object, module or sequence of instructions (sometimes referred to as computer programs). Invocation interfaces to these routines can be exposed to a software development community as an API (Application Programming Interface). The computer programs typically comprise one or more instructions set at various times in various memory and storage devices in a computer, and that, when read and executed by one or more processors in a computer, cause the computer to perform operations necessary to execute elements involving the various aspects.

A computer-readable medium can be used to store software and data which when executed by a computing device causes the device to perform various methods. The executable software and data may be stored in various places including, for example, ROM, volatile RAM, non-volatile memory and/or cache. Portions of this software and/or data may be stored in any one of these storage devices. Further, the data and instructions can be obtained from centralized servers or peer to peer networks. Different portions of the data and instructions can be obtained from different centralized servers and/or peer to peer networks at different times and in different communication sessions or in a same communication session. The data and instructions can be obtained in entirety prior to the execution of the applications. Alternatively, portions of the data and instructions can be obtained dynamically, just in time, when needed for execution. Thus, it is not required that the data and instructions be on a computer-readable medium in entirety at a particular instance of time.

Examples of computer-readable media include, but are not limited to, recordable and non-recordable type media such as volatile and non-volatile memory devices, read only memory (ROM), random access memory (RAM), flash memory devices, solid-state drive storage media, removable disks, magnetic disk storage media, optical storage media (e.g., Compact Disk Read-Only Memory (CD ROMs), Digital Versatile Disks (DVDs), etc.), among others. The computer-readable media may store the instructions. Other examples of computer-readable media include, but are not limited to, non-volatile embedded devices using NOR flash or NAND flash architectures. Media used in these architectures may include un-managed NAND devices and/or managed NAND devices, including, for example, eMMC, SD, CF, UFS, and SSD.

In general, a non-transitory computer-readable medium includes any mechanism that provides (e.g., stores) information in a form accessible by a computing device (e.g., a computer, mobile device, network device, personal digital assistant, manufacturing tool having a controller, any device with a set of one or more processors, etc.). A “computer-readable medium” as used herein may include a single medium or multiple media (e.g., that store one or more sets of instructions).

In various embodiments, hardwired circuitry may be used in combination with software and firmware instructions to implement the techniques. Thus, the techniques are neither limited to any specific combination of hardware circuitry and software nor to any particular source for the instructions executed by a computing device.

Various embodiments set forth herein can be implemented using a wide variety of different types of computing devices. As used herein, examples of a “computing device” include, but are not limited to, a server, a centralized computing platform, a system of multiple computing processors and/or components, a mobile device, a user terminal, a vehicle, a personal communications device, a wearable digital device, an electronic kiosk, a general purpose computer, an electronic document reader, a tablet, a laptop computer, a smartphone, a digital camera, a residential domestic appliance, a television, or a digital music player. Additional examples of computing devices include devices that are part of what is called “the internet of things” (IOT). Such “things” may have occasional interactions with their owners or administrators, who may monitor the things or modify settings on these things. In some cases, such owners or administrators play the role of users with respect to the “thing” devices. In some examples, the primary mobile device (e.g., an Apple iPhone) of a user may be an administrator server with respect to a paired “thing” device that is worn by the user (e.g., an Apple watch).

In some embodiments, the computing device can be a computer or host system, which is implemented, for example, as a desktop computer, laptop computer, network server, mobile device, or other computing device that includes a memory and a processing device. The host system can include or be coupled to a memory sub-system so that the host system can read data from or write data to the memory sub-system. The host system can be coupled to the memory sub-system via a physical host interface. In general, the host system can access multiple memory sub-systems via a same communication connection, multiple separate communication connections, and/or a combination of communication connections.

In some embodiments, the computing device is a system including one or more processing devices. Examples of the processing device can include a microcontroller, a central processing unit (CPU), special purpose logic circuitry (e.g., a field programmable gate array (FPGA), an application specific integrated circuit (ASIC), etc.), a system on a chip (SoC), or another suitable processor.

In one example, a computing device is a controller of a memory system. The controller includes a processing device and memory containing instructions executed by the processing device to control various operations of the memory system.

Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software or any combination thereof.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

What is claimed is:

1. An apparatus comprising:
a memory array comprising memory cells arranged as memory cell pairs, each pair configured to store a logical bit;
bias circuitry configured to select a first memory cell pair having first and second memory cells by applying voltages to a wordline and to first and second bitlines to select the first and second memory cells, wherein the bias circuitry is further configured to reduce a magnitude of at least one of the voltages on the first or second bitlines after at least one of the first or second memory cells switches;
sensing circuitry configured to read first data stored by the first memory cell pair; and
a buffer configured to store the read first data.

2. The apparatus of claim 1, wherein the buffer includes a first latch, the apparatus further comprising:
a second latch configured to store data to be written to the memory array; and
a controller configured to:
receive a write command with second data to be stored;
in response to receiving the write command, store the second data in the second latch;
compare the first and second data;
determine, based on comparing the first and second data, that the second data is not stored in the memory array; and
change a logic state for each of the first and second memory cells to store the second data.

3. The apparatus of claim 2, wherein changing the logic state for the first and second memory cells is performed in response to receiving a pre-charge command.

4. The apparatus of claim 2, wherein changing the logic state comprises applying, using the bias circuitry, at least one pulse to each of the first and second memory cells.

5. The apparatus of claim 1, further comprising a controller configured to:
receive an activate command; and
in response to receiving the activate command, cause the sensing circuitry to read the first data by determining a logic state of the first memory cell pair.

6. The apparatus of claim 5, wherein the controller is further configured to:
after receiving the activate command, receive a read command; and
in response to receiving the read command, retrieve the first data from the buffer.

7. The apparatus of claim 1, wherein the first memory cell is selected using the wordline and the first bitline, and the second memory cell is selected using the wordline and the second bitline.

8. The apparatus of claim 1, further comprising a controller configured to:
determine that at least one of the first or second memory cells has switched; and
in response to determining that at least one of the first or second memory cells has switched, cause the bias circuitry to reduce the magnitude of the voltages on the first and second bitlines.

9. The apparatus of claim 1, further comprising a controller configured to:
determine to refresh a partition of the memory array that includes the first memory cell pair; and
in response to determining to refresh the partition, invert a logic state of the first and second memory cells.

10. The apparatus of claim 9, wherein:
data is read from the memory array in response to commands from a host device, and the read data is provided to the host device within a read completion time;
a read latency for reading data stored in the memory array is less than the read completion time; and
the partition is refreshed within a time period starting after data is read from the memory array, and prior to the read completion time.

11. The apparatus of claim 10, wherein the read latency corresponds to a row column delay time, and the read completion time corresponds to a row cycle time.

12. The apparatus of claim 9, wherein at least a portion of a page of data is stored in the partition, and inverting the logic state is performed as part of an inversion of the page.

13. The apparatus of claim 9, further comprising a counter configured to count each access to the partition, wherein determining to refresh the partition comprises:
generating a random number;
incrementing the counter on each access to the partition;
comparing a value of the counter to the random number; and
determining that the value of the counter equals the random number.

14. The apparatus of claim 13, wherein:
the buffer includes a cache configured to store data previously read from the memory array prior to a current access to the partition; and
the counter is not incremented if data to be read for the current access will be read from the cache instead of from the memory array.

15. The apparatus of claim 13, wherein:
when the counter reaches a threshold, the counter is reset and a new random number is generated; and
the value of the counter is compared to the new random number on subsequent accesses to the partition.

16. The apparatus of claim 1, wherein at least one of the first or second memory cells switches when the sensing circuitry is reading the first data stored by the first memory cell pair.

17. The apparatus of claim 1, wherein the wordline voltage is applied as a ramp of increasing magnitude when reading the first data.

18. The apparatus of claim 1, wherein:
the voltage applied to the first and second bitlines is of a first polarity; and
the voltage applied to the wordline is of a second polarity opposite to the first polarity.

19. The apparatus of claim 18, further comprising a controller configured to:
receive a write command with second data to be stored in the memory array; and
after receiving the write command, initiate a programming operation to change a logic state of the first and second memory cells to correspond to the second data.

20. The apparatus of claim 19, wherein the first memory cell switches when the sensing circuitry reads the first data, and the programming operation comprises:
applying a first programming pulse to program the second memory cell, wherein applying the first programming pulse comprises applying a voltage to the wordline at the second polarity; and
applying a second programming pulse to program the first memory cell, wherein applying the second programming pulse comprises applying a voltage to the wordline at the first polarity.

21. The apparatus of claim 20, wherein the second cell is programmed prior to programming the first cell.

22. The apparatus of claim 20, wherein the first cell is programmed prior to programming the second cell.

23. An apparatus comprising:
a latch configured to store data for sending to a host;
a memory array comprising memory cells arranged as memory cell pairs, each pair configured to store a logical bit; and
a controller configured to:
receive a first command from a host that initiates a read operation;
select, using access lines, a first memory cell pair having first and second memory cells, wherein the first memory cell pair is located in a first partition of the memory array, and the first memory cell pair stores first data;
access the first partition to read the first data;
store the first data in the latch;
in response to accessing the first partition, determine whether to perform a refresh operation; and
in response to determining to perform the refresh operation, refresh the first partition.

24. The apparatus of claim 23, wherein the first command is an activate command, the controller is further configured to receive a read command from the host, and the first data is sent to the host in response to receiving the read command.

25. The apparatus of claim 23, wherein the first partition is refreshed after reading the first data and prior to completion of the read operation.

26. The apparatus of claim 23, wherein the controller is further configured to:
receive a write command from the host with second data to be stored; and
store the second data by changing a logic state of the first and second memory cells.

27. The apparatus of claim 26, wherein the controller is further configured to receive a pre-charge command after receiving the write command, and the second data is stored in response to receiving the pre-charge command.

28. The apparatus of claim 26, wherein the access lines include first and second bitlines and a wordline.

29. The apparatus of claim 28, wherein:
a first voltage is applied to the first and second bitlines to read the first data; and
a second voltage of a greater magnitude than the first voltage is applied to the first and second bitlines to change the logic state of the first and second memory cells.

30. The apparatus of claim 23, wherein the controller is further configured to reduce a magnitude of a voltage on at least one of the access lines after at least one of the first or second memory cells switches.

31. A method comprising:
in response to receiving a command from a host, selecting a first memory cell pair having first and second memory cells by applying voltages to a wordline and to first and second bitlines;
reading first data stored by the first memory cell pair;
while reading the first data, detecting that at least one of the first or second memory cells switches;
after detecting that at least one of the first or second memory cells switches, reducing a magnitude of a voltage applied to at least one of the first bitline, the second bitline, or the wordline; and
storing the read first data for sending to the host.

32. The method of claim 31, wherein a first partition of the memory array is accessed when reading the first data, the method further comprising:
determining whether to perform a refresh operation for the first partition; and
in response to determining to perform the refresh operation, refresh at least the first memory cell pair.
